(19) United States
(12) Patent Application Publication
(10) Pub. No.: US 2019/0352767 A1
(43) Pub. Date: Nov. 21, 2019

(54) Reflective Coating Substrate

(71) Applicant: KCC Corporation, Seoul (KR)

(72) Inventors: Bona Yu, Gunsan-si, Jeollabuk-do (KR); Hyunmin Kang, Suwon-si, Gyeonggi-do (KR); Sanglool Kim, Yeoju-si, Gyeonggi-do (KR); Hyounjoo Lee, Busanjin-gu, Busan (KR); Daehwan Kim, Yongin-si, Gyeonggi-do (KR); Jungho Ahn, Hwaseong-si, Gyeonggi-do (KR)

(73) Assignee: KCC Corporation, Seoul (KR)

(21) Appl. No.: 16/482,875

(22) PCT Filed: Feb. 12, 2018
(86) PCT No.: PCT/KR2018/001834

§ 371 Date: Aug. 1, 2019

(30) Foreign Application Priority Data
Feb. 17, 2017 (KR) 10-2017-0021421

(51) Int. Cl. C23C 14/20; G02B 5/08; G02B 1/14; C23C 14/34; C23C 14/18

(52) U.S. Cl. CPC C23C 14/205; G02B 5/0808; C23C 14/185; C23C 14/34; G02B 1/14

(57) ABSTRACT

The present invention provides a reflective coating substrate comprising a transparent substrate, an underlayer formed on the transparent substrate, and a reflective metal layer formed on the underlayer, wherein the underlayer includes an oxide, oxynitride, or nitride of zinc-aluminum.

### TECHNICAL FIELD

The present invention relates to a reflective coating substrate.

### BACKGROUND ART

A reflective coating substrate is a substrate coated with a reflective metal layer comprising a metal with high reflectance for the purpose of increasing reflection. Generally, silver (Ag) is used for the reflective metal layer. However, there is a problem in that a wet chemical method conventionally used for the deposition of silver to form a reflective metal layer is accompanied by the generation of cleaning water containing chemical agents, silver, copper, and tin which require additional costs and equipment for environmentally friendly disposal thereof. Accordingly, a sputtering method has been proposed as a silver deposition method.

However, silver deposition by a sputtering method has a problem in that silver is weakly adhered to a glass or plastic material which is commonly used as the substrate, resulting in a reflective coating substrate with relatively low durability.

Therefore, there have been proposed reflective coating substrates produced by a conventional sputtering method but comprising a nickel-chromium nitride layer and/or the like formed between a substrate and a reflective metal layer so that the adherence between silver and the substrate can be improved, however, there is still a disadvantage in that either relatively low reflectance is attained or a desired level of durability is not easily secured.

Accordingly, there is a demand for the development of a reflective coating substrate exhibiting excellent durability while ensuring high reflectance despite being produced by a sputtering method.

(Patent Document 0001) Japanese Patent Registration No. 2,831,932

### DISCLOSURE

### Technical Problem

The present invention is directed to providing a reflective coating substrate exhibiting excellent durability while ensuring high reflectance despite being produced by a sputtering method.

### Technical Solution

Provided is a reflective coating substrate comprising a transparent substrate, an underlayer provided on the transparent substrate, and a reflective metal layer provided on the underlayer, wherein the underlayer comprises an oxide, oxynitride, or nitride of zinc-aluminum.

In one embodiment of the present invention, the underlayer may have a thickness of 2 nm to 10 nm.

In one embodiment of the present invention, the reflective coating substrate may further comprise a metal protective layer provided on the reflective metal layer and an inorganic protective layer provided on the metal protective layer.

In one embodiment of the present invention, the reflective coating substrate may further comprise a UV protection layer provided on the inorganic protective layer.

### Advantageous Effects

The reflective coating substrate of the present invention exhibits high reflectance and excellent durability due to having an underlayer provided between a transparent substrate and a reflective metal layer.

### DESCRIPTION OF DRAWINGS

FIG. 1 is a cross-sectional view for schematically illustrating a reflective coating substrate according to one embodiment of the present invention.

### MODES OF THE INVENTION

Hereinafter, the present invention will be described in more detail.

In one embodiment thereof, the present invention relates to a reflective coating substrate comprising a transparent substrate, an underlayer provided on the transparent substrate, and a reflective metal layer provided on the underlayer.

In one embodiment of the present invention, the transparent substrate may be a glass substrate or a plastic substrate, but the present invention is not limited thereto.

In this case, the glass substrate may be made of, for example, soda lime glass, soda-lime-silicate glass, borosilicate glass, lead glass, or the like, but the present invention is not limited thereto. In addition, annealed or heat-treated glass may be used if necessary.

Meanwhile, the plastic substrate may be a plastic substrate comprising one or more types of polymers selected from the group consisting of polycarbonate, polymethyl methacrylate, polyethylene terephthalate, polybutylene terephthalate, polyimide, and Bakelite, but the present invention is not limited thereto.

The thickness of the transparent substrate may be freely selected, for example, within a range of 1 to 10 mm, depending on the purpose of use.

In one embodiment of the present invention, the underlayer serves to improve the durability of the reflective coating substrate by reinforcing the adherence between the transparent substrate and the reflective metal layer.

In the reflective coating substrate according to one embodiment of the present invention, since the underlayer comprises an oxide, oxynitride, or nitride of zinc-aluminum, not only excellent adherence between the transparent substrate and the reflective metal layer is attained, but also a decrease in reflectance can be minimized.

In the reflective coating substrate according to one embodiment of the present invention, the decrease in reflectance of the visible light incident on the transparent substrate toward the reflective metal layer may be minimized due to the underlayer provided between the transparent substrate and the reflective metal layer.

The reflective coating substrate according to one embodiment of the present invention may exhibit a visible-light reflectance of 85% or more, for example 85% to 90%, and particularly 87% to 90%. Here, the visible-light reflectance may refer to reflectance in a 380 nm to 780 nm wavelength band.

The above-described zinc-aluminum oxide may be represented by ZnAlOₓ, wherein x may be 0.9≤x≤1.1.

The above-described zinc-aluminum oxynitride may be represented by ZnAlOₓN_{y}, wherein x may be 0.4≤x≤0.6, and y may be 0.4≤y≤0.6.

The above-described zinc-aluminum nitride may be represented by ZnAlNₓ, wherein x may be 0.8≤x≤1.2.

The above-described underlayer may have a thickness of 2 nm to 10 nm, for example, 2 nm to 5 nm. When the underlayer has a thickness of less than 2 nm, the adherence provided by the underlayer may be relatively low, and when the underlayer has a thickness of greater than 10 nm, reflectance may be sacrificed.

In one embodiment of the present invention, the above-described reflective metal layer is provided on the underlayer and, due to inclusion of a metal with high reflectance, may improve the reflectance of the reflective coating substrate.

The reflective metal layer may comprise silver (Ag), a silver alloy, aluminum (Al), platinum (Pt), titanium (Ti), or an alloy thereof. In particular, the reflective metal layer may comprise silver or a silver alloy for the improvement of visible-light reflectance and adherence.

Here, the silver alloy may be selected from the group consisting of a silver-tin alloy, a silver-indium alloy, a silver-rhodium alloy, a silver-ruthenium alloy, a silver-gold alloy, a silver-palladium alloy, a silver-nickel alloy, a silver-selenium alloy, and a silver-antimony alloy.

In addition, the reflective metal layer may have a thickness of 50 nm to 100 nm, for example, 50 nm to 70 nm, and as another example, 55 nm to 60 nm. When the reflective metal layer has a thickness of less than 50 nm, relatively low reflectance may be attained, and when the reflective metal layer has a thickness of greater than 100 nm, relatively low reflectance improvement efficiency may be exhibited.

Meanwhile, the reflective coating substrate according to one embodiment of the present invention may further comprise a metal protective layer provided on the reflective metal layer and an inorganic protective layer provided on the metal protective layer.

In one embodiment of the present invention, the metal protective layer may prevent the oxidation of the reflective metal layer.

The metal protective layer may comprise one or more metals selected among elemental metals of Group 2-16 of the periodic table, such as nickel, iron, aluminum, copper, chromium, titanium, cobalt, zinc, tin, zirconium, molybdenum, tungsten, niobium, indium, lead, and bismuth, or a nitride thereof, but the present invention is not limited thereto. In particular, the metal protective layer may comprise nickel, a nickel-chromium alloy, or a nickel-chromium nitride.

The metal protective layer may have a thickness of 1.2 nm to 10 nm. When the metal protective layer has a thickness of less than 1.2 nm, relatively low salt-water resistance and relatively low scratch resistance may be exhibited, and when the metal protective layer has a thickness of greater than 10 nm, the durability of the reflective coating substrate may be sacrificed.

In one embodiment of the present invention, the above-described inorganic protective layer serves to improve durability.

The inorganic protective layer may comprise a silicon oxide or a silicon nitride.

The inorganic protective layer may have a thickness of 5 nm to 30 nm, for example, 10 nm. When the inorganic protective layer has a thickness of less than 5 nm, relatively low scratch resistance may be exhibited, and when the inorganic protective layer has a thickness of greater than 30 nm, relatively low productivity may be exhibited.

Meanwhile, the reflective coating substrate according to one embodiment of the present invention may further comprise a UV protection layer provided on the inorganic protective layer.

The UV protection layer serves to improve the durability, particularly scratch resistance, of the reflective coating substrate.

The UV protection layer may comprise urethane acrylate, isobornyl acrylate (IBOA), lauryl acrylate, an alpha-amino ketone, and the like.

The UV protection layer may have a thickness of 10 μm to 100 μm. When the UV protection layer has a thickness of less than 10 μm, relatively low durability may be attained, and when the UV protection layer has a thickness of greater than 100 μm, relatively low productivity and relatively low processability may be exhibited.

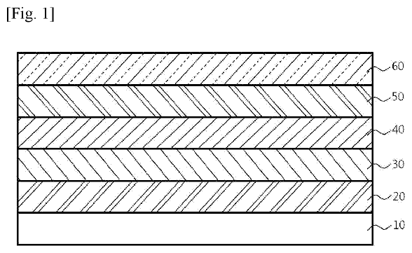

FIG. 1 is a cross-sectional view for schematically illustrating a reflective coating substrate according to one embodiment of the present invention.

Referring to FIG. 1, a reflective coating substrate according to one embodiment of the present invention comprises a transparent substrate 10, an underlayer 20 provided on the transparent substrate, a reflective metal layer 30 provided on the underlayer, a metal protective layer 40 provided on the reflective metal layer, an inorganic protective layer 50 provided on the metal protective layer, and a UV protection layer 60 provided on the inorganic protective layer.

In one embodiment of the present invention, each of the above-described layers may be deposited by a suitable vacuum deposition method, particularly by a physical vapor deposition (PVD) method such as a sputtering method or by a chemical vapor deposition (CVD) method such as low-pressure CVD, atmospheric pressure CVD, or plasma-based CVD.

In particular, all of the above-described layers may be deposited in a continuous manner by a sputtering method. A sputtering method is a method capable of depositing an oxide layer or a nitride layer by the sputtering of corresponding target metal(s) in the presence oxygen or nitrogen, respectively.

Such a sputtering method may be particularly suitable for a large-sized transparent substrate.

Such a sputtering method enables the deposition of a wide range of materials in a single vacuum chamber, and can produce a layer having higher chemical purity than a conventional wet chemical method.

Furthermore, when a sputtering method is used, the risk of environmental pollution caused by a wet chemical method can be prevented.

The reflective coating substrate according to one embodiment of the present invention can be used for construction or interior decoration, particularly for interior decoration in a high temperature and high humidity environment. For example, the reflective coating substrate according to one embodiment of the present invention can be used in bathroom basins, bathroom furniture, specialty furniture such as built-in cabinets, and the like.

Hereinafter, the present invention will be described in more detail with reference to examples and comparative examples. It should be apparent to those skilled in the art that these examples and comparative examples are provided only to illustrate the present invention, and that the scope of the present invention is not limited to the examples.

### Examples 1 to 5 and Comparative Examples 1 to 3: Preparation of Reflective Coating Substrate

A reflective coating substrate having a lamination structure as shown in the following Table 1 was prepared by depositing each of the layers on a 5 mm soda lime glass material. Each of the layers was deposited using an in-line sputtering system (BMC). Here, the value of x in SiNₓ was 1.06 to 1.60, the value of x in ZnAlOₓ was 0.80 to 1.20, and the Ni:Cr ratio in NiCr was 80:20.

In addition, the value of x in NiCrNₓ was 0.8 to 1.2.

TABLE 1

| | | | | Metal | Inorganic | |
|---|---|---|---|---|---|---|
| | | | Reflective | protective | protective | UV protection |
| Classification | | Underlayer | metal layer | layer | layer | layer |
| Comparative | Components | — | Ag | NiCr | SiNₓ | — |
| Example 1 | Thickness (nm) | — | 55 | 1.2 | 10 | — |
| Comparative | Components | SiNₓ | Ag | NiCr | SiNₓ | — |
| Example 2 | Thickness (nm) | 10 | 55 | 1.2 | 10 | — |
| Comparative | Components | NiCrNₓ | Ag | NiCr | SiNₓ | — |
| Example 3 | Thickness (nm) | 3 | 55 | 1.2 | 10 | — |
| Example 1 | Components | ZnAlOₓ | Ag | NiCr | SiNₓ | — |
| | Thickness (nm) | 10 | 55 | 1.2 | 10 | — |
| Example 2 | Components | ZnAlOₓ | Ag | NiCr | SiNₓ | — |
| | Thickness (nm) | 3 | 55 | 1.2 | 10 | — |
| Example 3 | Components | ZnAlOₓ | Ag | NiCr | SiNₓ | — |
| | Thickness (nm) | 2 | 55 | 1.2 | 10 | — |
| Example 4 | Components | ZnAlOₓ | Ag | NiCr | SiNₓ | UA |
| | Thickness (nm) | 2 | 55 | 1.2 | 10 | UA |
| Example 5 | Components | ZnAlOₓ | Ag | NiCr | SiNₓ | — |
| | Thickness (nm) | 2 | 55 | 10 | 10 | — |

UA: Urethane acrylate (number-average molecular weight: 8,000)

### Experimental Example 1

The physical properties of the reflective coating substrates produced according to the Examples and the Comparative Examples were evaluated by the following methods, and the results thereof are shown in the following Table 2.

(1) Reflectance The reflectance of light of 380 nm to 780 nm in wavelength at a glass surface of a reflective coating substrate was measured using LAMBDA 950 (PerkinElmer, Inc.).

(2) Salt-Water Resistance

The salt-water resistance was evaluated by immersing a specimen in a 3% NaCl solution and measuring the time taken for a coating thereof to be damaged.

(3) Scratch Resistance

The scratch resistance was evaluated by spraying a solution containing quartz powder onto a coating and brushing the sprayed solution back and forth (one round) ten or more times and then checking the coating for any damage.

TABLE 2

| Classification | Reflectance (%) | Salt-water resistance | Scratch resistance |
|---|---|---|---|
| Comparative Example 1 | 89.2 | 2 hours | Damaged by 10 rounds |
| Comparative Example 2 | 83.4 | 1 hour | Damaged by 10 rounds |
| Comparative Example 3 | 74.5 | 24 hours or more | Damaged by 10 rounds |
| Example 1 | 87.5 | 24 hours or more | Damaged by 10 rounds |
| Example 2 | 87.9 | 24 hours or more | Damaged by 10 rounds |
| Example 3 | 88.5 | 24 hours or more | Damaged by 10 rounds |
| Example 4 | 88.5 | 24 hours or more | No damage by 1,000 or |
| | | | more rounds |
| Example 5 | 88.7 | 24 hours | Damaged by 10 rounds |

Referring to Table 2, the reflective coating substrates of Examples 1 to 5 exhibited excellent salt-water resistance and excellent scratch resistance while exhibiting a high reflectance of 85% or more. On the other hand, the reflective coating substrate of Comparative Example 1, which does not comprise an underlayer, exhibited high reflectance but low salt-water resistance. Meanwhile, the reflective coating substrates of Comparative Examples 2 and 3, an underlayer of which does not comprise an oxide, oxynitride, or nitride of zinc-aluminum, exhibited either low reflectance or low salt-water resistance.

While particular embodiments of the present invention have been described in detail, it is clearly understood by those skilled in the art that such detailed descriptions are merely illustrative of the invention and are not intended to limit the scope of the invention thereto. It will be understood by those skilled in the art that various changes and modifications may be made based on the disclosure of the invention without departing from the spirit and scope of the invention.

Accordingly, the actual scope of the invention is defined by the appended claims and their equivalents.

1. A reflective coating substrate comprising a transparent substrate, an underlayer provided on the transparent substrate, and a reflective metal layer provided on the underlayer, wherein the underlayer comprises an oxide, oxynitride, or nitride of zinc-aluminum.

2. The reflective coating substrate of claim 1, wherein the transparent substrate is a glass substrate or a plastic substrate comprising one or more types of polymers selected from the group consisting of polycarbonate, polymethyl methacrylate, polyethylene terephthalate, polybutylene terephthalate, polyimide, and Bakelite.

3. The reflective coating substrate of claim 1, wherein the underlayer has a thickness of 2 nm to 10 nm.

4. The reflective coating substrate of claim 1, wherein the reflective metal layer comprises one or more selected from the group consisting of silver (Ag), a silver alloy, aluminum (Al), platinum (Pt), and titanium (Ti).

5. The reflective coating substrate of claim 1, wherein the reflective metal layer has a thickness of 50 nm to 100 nm.

6. The reflective coating substrate of claim 1, further comprising a metal protective layer provided on the reflective metal layer and an inorganic protective layer provided on the metal protective layer.

7. The reflective coating substrate of claim 6, wherein the metal protective layer comprises nickel, a nickel-chromium alloy, or a nickel-chromium nitride.

8. The reflective coating substrate of claim 6, wherein the metal protective layer has a thickness of 1.2 nm to 10 nm.

9. The reflective coating substrate of claim 6, wherein the inorganic protective layer comprises a silicon nitride or a silicon oxide.

10. The reflective coating substrate of claim 6, wherein the inorganic protective layer has a thickness of 5 nm to 30 nm.

11. The reflective coating substrate of claim 6, further comprising a UV protection layer provided on the inorganic protective layer.

12. The reflective coating substrate of claim 11, wherein the UV protection layer comprises one or more selected from the group consisting of urethane acrylate, isobornyl acrylate (IBOA), lauryl acrylate, and an alpha-amino ketone.

13. The reflective coating substrate of claim 11, wherein the UV protection layer has a thickness of 10 μm to 100 μm.

14. The reflective coating substrate of claim 1, which is used for construction or interior decoration.
